(19) United States
(12) Patent Application Publication
(10) Pub. No.: US 2001/0026114 A1
(43) Pub. Date: Oct. 4, 2001

(54) Multilayer piezoelectric actuator with electrodes reinforced in conductivity

(75) Inventors: Fumio Takao, Fukuoka-shi (JP); Hideaki Kosaka, Tatsuno-shi (JP); Narumi Ogura, Shiso-gun (JP); Kazunobu Matsukawa, Shikama-gun (JP)

Correspondence Address: FRISHAUF, HOLTZ, GOODMAN &, LANGER & CHICK, PC, 767 THIRD AVENUE, 25TH AVE, NEW YORK, NY, 10017-2023, US

(73) Assignee: Tokin Ceramics Corporation, Shiso-gun (JP)

(21) Appl. No.: 09/817,093

(22) Filed: Mar. 26, 2001

(30) Foreign Application Priority Data
Mar. 29, 2000 (JP) 92201/2000

(51) Int. Cl. H01L 41/04

(52) U.S. Cl. 310/364; 310/357

(57) ABSTRACT

In a multilayer piezoelectric actuator device having a laminated structure (3) of a plurality of piezoelectric elements (3a) and a plurality of internal electrodes (3b) alternately stacked, a pair of external electrodes (5) are connected alternately to said internal electrodes. Each of the external electrodes has an electrode layer (11) and a composite layer (13). The electrode layer is formed on a side surface of the laminated structure. The composite layer is formed on the electrode layer and made of a conductive resin including a conductive material. It is preferable that a carbon paper (7) is placed on the composite layer.

### BACKGROUND OF THE INVENTION

This invention relates to a multilayer piezoelectric actuator device comprising a laminated structure including a plurality of piezoelectric layers and a plurality of internal electrode layers alternately stacked and, in particular, to a multilayer piezoelectric actuator device comprising an external electrode connected to the internal electrodes.

Referring to FIGS. 1 and 2, a conventional multilayer piezoelectric actuator device will be described. The multilayer piezoelectric actuator device illustrated in FIGS. 1 and 2 comprises a laminated structure 53 including a plurality of piezoelectric ceramics layers 53a and a plurality of internal electrodes 53b alternately laminated or stacked, a pair of external electrodes 55 formed on opposite side surfaces of the laminated structure 53 and connected alternately to the internal electrodes 53b, and a pair of external lead wires 57 connected to the external electrodes 55, respectively. On each of the opposite side surfaces of the laminated structure 53, the internal electrodes 53b are alternately covered with insulating glass coatings 53c and alternately uncovered or exposed. Therefore, the internal electrodes 53b are alternately electrically insulated from and alternately electrically connected to each of the external electrodes 55. In other words, the internal electrodes 53b are connected alternately to one and the other of the external electrodes 55. The external electrodes 55 are made of, for example, Ag (silver) or Ag/Pd (palladium).

In the multilayer piezoelectric actuator device mentioned above, the laminated structure 53 repeats quick extension and contraction when the actuator device is driven. This results in occurrence of fatigue in the piezoelectric ceramics layers 53a and the external electrodes 55. If the actuator device is driven for a long period of time, a crack 59 may be produced as illustrated in FIG. 1 and, in the worst case, the external electrodes 55 will be torn off. It is noted here that each of the external lead wires 57 is connected to the external electrode 55 only at an upper part of the laminated structure 53. Therefore, if the external electrode 55 is tom off, a lower part of the laminated structure 53 is no longer operable.

### SUMMARY OF THE INVENTION

It is therefore an object of this invention to provide a multilayer piezoelectric actuator device capable of suppressing degradation in function even if it is driven for a long period of time.

Other objects of the present invention will become clear as the description proceeds.

According to an aspect of this invention, there is provided a multilayer piezoelectric actuator device which comprises a laminated structure including a plurality of piezoelectric elements and a plurality of internal electrodes alternately stacked, and a pair of external electrodes connected alternately to the internal electrodes, each of the external electrodes comprising an electrode layer formed on a first side surface of the laminated structure and a first composite layer formed on the electrode layer and made of a conductive resin including a first conductive material.

According to another aspect of this invention, there is provided a multilayer piezoelectric actuator device which comprises a laminated structure including a plurality of piezoelectric elements and a plurality of internal electrodes alternately stacked, a pair of external electrodes connected alternately to the internal electrodes, and a carbon paper, each of the external electrodes comprising an electrode layer formed on a first side surface of the laminated structure and a first composite layer formed on the electrode layer and made of a conductive resin including a first conductive material, the carbon paper being placed on the first composite layer, the electrode layer and the carbon paper being adhered to each other by the first composite layer.

According to still another aspect of this invention, there is provided a laminated structure including a plurality of piezoelectric elements and a plurality of internal electrodes alternately stacked, and a pair of external electrodes connected alternately to the internal electrodes, each of the external electrodes comprising an electrode layer formed on a first side surface of the laminated structure and a first composite layer formed on the electrode layer and made of a conductive resin including a first conductive material, the multilayer piezoelectric actuator device further comprising a second composite layer formed on the first composite layer, the second composite layer being made of a conductive resin including a second conductive material and a carbon fiber.

### BRIEF DESCRIPTION OF THE DRAWING

FIG. 1 is a front view of a conventional multilayer piezoelectric actuator device;

FIG. 2 is a bottom view of the conventional multilayer piezoelectric actuator device illustrated in FIG. 1;

FIG. 3 is a front view of a multilayer piezoelectric actuator device according to a first embodiment of this invention;

FIG. 4 is a bottom view of the multilayer piezoelectric actuator device illustrated in FIG. 3;

FIG. 5 is a sectional view taken along a line V-V in FIG. 3;

FIG. 6 is a front view of a multilayer piezoelectric actuator device according to a second embodiment of this invention;

FIG. 7 is a bottom view of the multilayer piezoelectric actuator device illustrated in FIG. 6;

FIG. 8 is a front view of a multilayer piezoelectric actuator device according to a third embodiment of this invention;

FIG. 9 is a bottom view of the multilayer piezoelectric actuator device illustrated in FIG. 8;

FIG. 10 is a front view of a multilayer piezoelectric actuator device according to a fourth embodiment of this invention; and

FIG. 11 is a bottom view of the multilayer piezoelectric actuator device illustrated in FIG. 10.

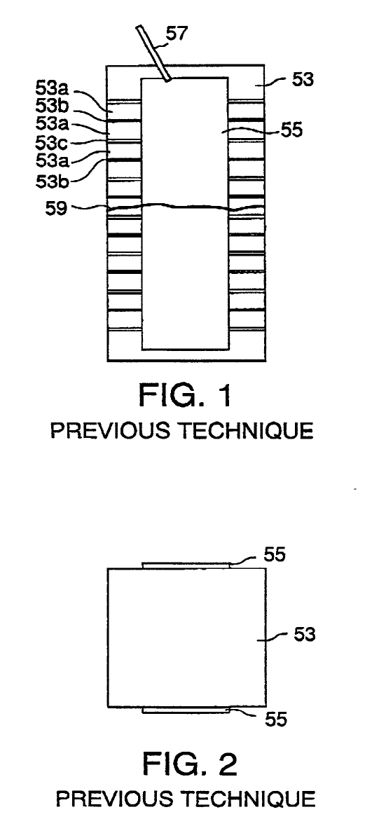

### DESCRIPTION OF THE PREFERRED EMBODIMENTS

Now, description will be made of several preferred embodiments of this invention with reference to the drawing.

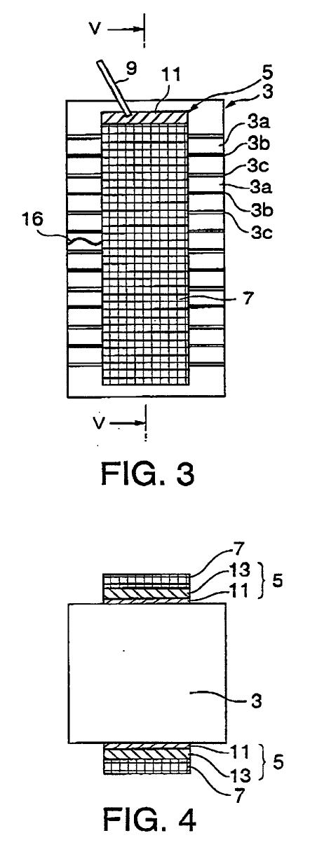

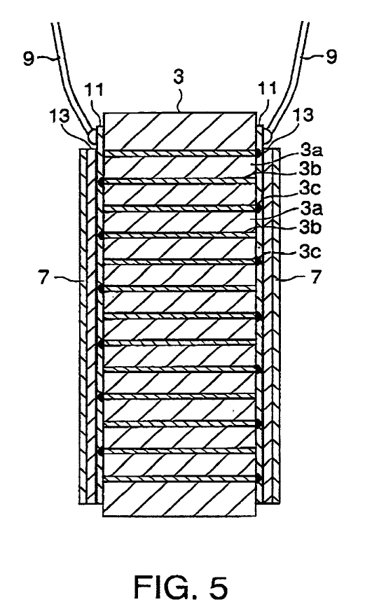

At first referring to FIGS. 3 through 5, a multilayer piezoelectric actuator device according to a first embodiment of this invention comprises a laminated structure 3 including a plurality of plate-like piezoelectric ceramics layers or piezoelectric elements 3a and a plurality of plate-like internal electrodes 3b alternately stacked, a pair of external electrodes 5 connected to the internal electrodes 3b on opposite side surfaces of the laminated structure 3, a pair of carbon papers 7 placed on the external electrodes 5, respectively, and a pair of external lead wires 9 connected to the external electrodes 5, respectively. On each of the opposite side surfaces of the laminated structure 3, the internal electrodes 3b are alternately covered with insulating glass coatings 3c and alternately uncovered or exposed. Therefore, the internal electrodes 3b are alternately electrically insulated from and alternately electrically connected to each of the external electrodes 5. In other words, the internal electrodes 3b are connected alternately to one and the other of the external electrodes 5. The external electrodes 6 are formed, for example, by firing Ag (silver) or Ag/Pd (palladium).

Each of the external electrodes 5 comprises an electrode layer 11 formed by firing, plating, or sputtering on each of the opposite side surfaces of the laminated structure 3 and a first composite layer 13 formed on the electrode layer 11. The electrode layer 11 is formed, for example, by firing Ag (silver) or Ag/Pd (palladium). The first composite layer 13 is a conductive resin layer including a first conductive material. The first conductive material is made of at least one selected from Ag, Au, Pt, Pd, Cu, Ni, and C and has a granular shape, a needle-like shape, or a fiber-like shape. The first composite layer 13 serves to adhere the carbon paper 7 to the electrode layer 11. The external lead wire 9 is connected to one end face of the electrode layer 11.

Next, description will be made in detail about a method of producing the above-mentioned multilayer piezoelectric actuator device.

At first, preparation is made of the laminated structure 3 having a size of 5 mm×5 mm×60 mm with the internal electrodes 3b alternately exposed on the opposite side surfaces. On each of the opposite side surfaces of the laminated structure 3, screen-printing using a silver paste is carried out with 2 mm wide and 50 mm long in order to form the electrode layer 11. Thereafter, firing is carried out to form the electrode layer 11. On the electrode layer 11, the first composite layer 13 is formed. The carbon paper 7 having the width of 4 mm, the length of 50 mm, and the thickness of 300 μm is placed on the first composite layer 13. Successively, the first composite layer 13 is heat treated to be set or cured so that the carbon paper 7 is adhered to the electrode layer 11. Finally the external lead wire 5 is connected to one end of the electrode layer 11.

The multilayer piezoelectric actuator device is driven, for example, by supplying a rectangular wave signal of 0-150V and 1 kHz to the external lead wires 5. In this case, if the actuator device is repeatedly driven a large number of times, for example, 10⁹ times, a crack 16 as illustrated in FIG. 3 may be produced due to the fatigue of each of the piezoelectric ceramics layers 3a and each of the electrode layers 11. In the worst case, such crack 16 may completely tear off the electrode layer 11. However, the first composite layer 13 as the conductive resin layer has a large extensibility and therefore keeps a conductive state without being tom off. Therefore, the multilayer piezoelectric actuator device is prevented from being degraded in function. In other words, the multilayer piezoelectric actuator device is improved in durability of the external electrodes 5.

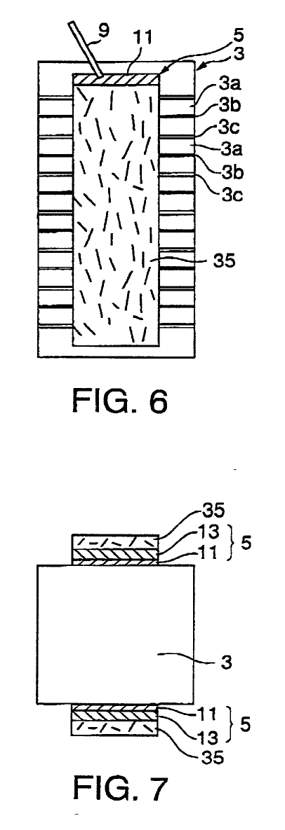

Referring to FIGS. 6 and 7, a multilayer piezoelectric actuator device according to a second embodiment of this invention will be described. Similar parts are designated by like reference numerals and will no longer be described.

In the multilayer piezoelectric actuator device illustrated in FIGS. 6 and 7, the carbon paper 7 used in the multilayer piezoelectric actuator device in FIGS. 3 to 5 is replaced by a second composite layer 35 having a conductivity and attached to the external electrode 5. The second composite layer 35 is made of a composite material including a carbon fiber, a second conductive material having at least one kind of shape selected from a granular shape, a needle-like shape, and a fiber-like shape, and thermosetting resin. As a shape of the second conductive material, use may be made of a granular shape or a fiber-like shape, The second conductive material is made of at least one kind of material selected from Ag, Au, Pt, Pd, Cu, Ni, and C. In the multilayer piezoelectric actuator 31 mentioned above, the external electrodes 5 are similarly improved in durability.

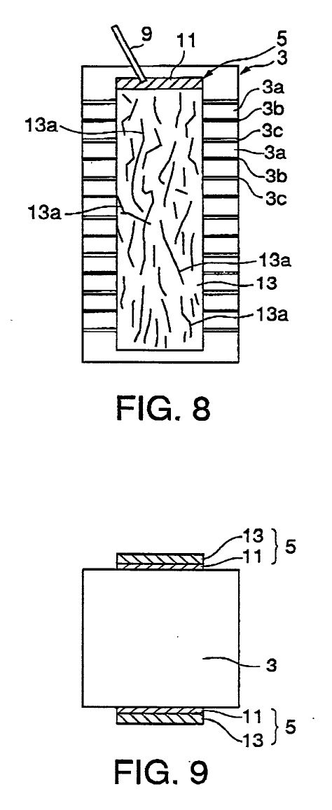

Referring to FIGS. 8 and 9, description will be made of a multilayer piezoelectric actuator device. Similar parts are designated by like reference numerals and will no longer be described.

In the multilayer piezoelectric actuator device illustrated in FIGS. 8 and 9, the first composite layer 13 is a conductive resin layer including conductive materials 13a as the first conductive material which are made of at least one kind of material selected from Ag, Au, Pt, Pd, Cu, Ni, and C. Each of the conductive materials 13a has a fiber-like shape extending relatively long in a laminate direction of the laminated structure 3. In the multilayer piezoelectric actuator device, the carbon paper and the second composite layer are not used.

Thus, since the first composite layer 13 includes the conductive materials each having a fiber-like shape and extending relatively long, the conductivity of the external electrode 5 can be maintained by the first composite layer 13 even if the electrode layer 11 is cracked or torn off.

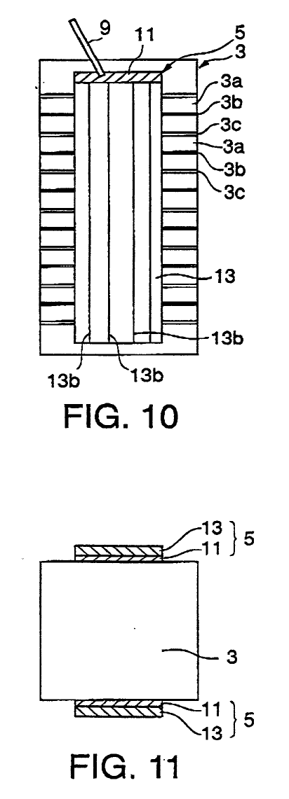

Referring to FIGS. 10 and 11, description will be made of a multilayer piezoelectric actuator device according to a fourth embodiment of this invention. Similar parts are designated by like reference numerals and will no longer be described.

In the multilayer piezoelectric actuator device illustrated in FIGS. 10 and 11, the first composite layer 13 is a conductive resin layer including conductive materials 13b as the first conductive material which are made of at least one kind of material selected from Ag, Au, Pt, Pd, Cu, Ni, and C. Each of the conductive materials 13b is formed as a fiber extending very long in the laminate direction of the laminated structure 3. In this embodiment, the carbon paper and the second composite layer are not used.

Thus, since the first composite layer 13 includes the fiber-like conductive material extending very long in the laminate direction of the laminated structure 3, the conductivity of the external electrode 5 can be maintained by the first composite layer 13 even if the electrode layer 11 is cracked or torn off.

As described above, with the multilayer piezoelectric actuator device of this invention, the electrical conductivity can be maintained by the conductive resin layer even if a crack is produced in the electrode layer of the external electrode. Therefore, durability and reliability can be improved. Even if the actuator device is driven for a long period of time, the degradation in function can be suppressed.

What is claimed is:

1. A multilayer piezoelectric actuator device comprising:
a laminated structure including a plurality of piezoelectric elements and a plurality of internal electrodes alternately stacked; and
a pair of external electrodes connected alternately to said internal electrodes,
each of said external electrodes comprising:
an electrode layer formed on a first side surface of said laminated structure; and
a first composite layer formed on said electrode layer and made of a conductive resin including a first conductive material.

2. A multilayer piezoelectric actuator device as claimed in claim 1, wherein said electrode layer is formed on the side surface of said laminated structure by one selected from firing, plating, and sputtering.

3. A multilayer piezoelectric actuator device as claimed in claim 1, wherein said first composite layer is adhered to said electrode layer by thermosetting.

4. A multilayer piezoelectric actuator device comprising:
a laminated structure including a plurality of piezoelectric elements and a plurality of internal electrodes alternately stacked:
a pair of external electrodes connected alternately to said internal electrodes; and
a carbon paper,
each of said external electrodes comprising:
an electrode layer formed on a first side surface of said laminated structure; and
a first composite layer formed on said electrode layer and made of a conductive resin including a first conductive material, said carbon paper being placed on said first composite layer, said electrode layer and said carbon paper being adhered to each other by said first composite layer.

5. A multilayer piezoelectric actuator device comprising:
a laminated structure including a plurality of piezoelectric elements and
a plurality of internal electrodes alternately stacked; and
a pair of external electrodes connected alternately to said internal electrodes,
each of said external electrodes comprising:
an electrode layer formed on a first side surface of said laminated structure; and
a first composite layer formed on said electrode layer and made of a conductive resin including a first conductive material,
said multilayer piezoelectric actuator device further comprising a second composite layer formed on said first composite layer, said second composite layer being made of a conductive resin including a second conductive material and a carbon fiber.

6. A multilayer piezoelectric actuator device as claimed in claim 5, wherein said electrode layer and said second composite layer are adhered to each other by said first composite layer.

7. A multilayer piezoelectric actuator device as claimed in claim 5, wherein said second conductive material comprises at least one kind of material selected from Ag, Au, Pt, Pd, Cu, Ni, and C.

8. A multilayer piezoelectric actuator device as claimed in claim 5, wherein said second conductive material has at least one kind of shape selected from a granular shape, a needle-like shape, and a fiber-like shape.

9. A multilayer piezoelectric actuator device as claimed in claim 1, wherein said first conductive material comprises at least one kind of material selected from Ag, Au, Pt, Pd, Cu, Ni, and C.

10. A multilayer piezoelectric actuator device as claimed in claim 1, wherein said first conductive material has at least one kind of shape selected from a granular shape, a needle-like shape, and a fiber-like shape.
